(19) United States
(12) Patent Application Publication
(10) Pub. No.: US 2023/0136139 A1
(43) Pub. Date: May 4, 2023

(54) FLASH MEMORY CHIP WITH SELF ALIGNED ISOLATION FILL BETWEEN PILLARS

(71) Applicant: Intel NDTM US LLC, Santa Clara, CA (US)

(72) Inventors: Anil CHANDOLU, Boise, ID (US); Prasanna SRINIVASAN, Santa Clara, CA (US); John HOPKINS, Milpitas, CA (US); Nancy LOMELI, Boise, ID (US)

(21) Appl. No.: 18/090,407

(22) Filed: Dec. 28, 2022

(51) Int. Cl. H01L 21/768

(52) U.S. Cl. CPC H01L 21/76879; H01L 21/76885; H01L 21/76816; H01L 21/76831

(57) ABSTRACT

An apparatus is described. The apparatus includes a flash memory chip having a self-aligned dielectric fill between pillars. The self-aligned dielectric fill extends through a polysilicon layer. The pillars have respective access transistors formed with the polysilicon layer. The self-aligned dielectric fill to electrically isolate the pillars.

### BACKGROUND OF THE INVENTION

As flash memory chip storage cell feature sizes continue to shrink, engineers are facing challenges packing storage cells closer together to effect increase memory chip storage capacity.

### BRIEF DESCRIPTION OF DRAWINGS

FIGS. 1, 2a, 2b, 3a and 3b pertain to a prior art flash memory;

FIGS. 4a, 4b, 4c, 4d, 4e, 4f, 4g, 4h, 4i, 4j, 4k, 41, 4m, 4n, 4o, 4p, 4q, 4r pertain to an improved flash memory;

FIG. 5 depicts a flash memory chip;

FIG. 6 depicts a solid state drive;

FIG. 7 depicts a computer system.

### DETAILED DESCRIPTION

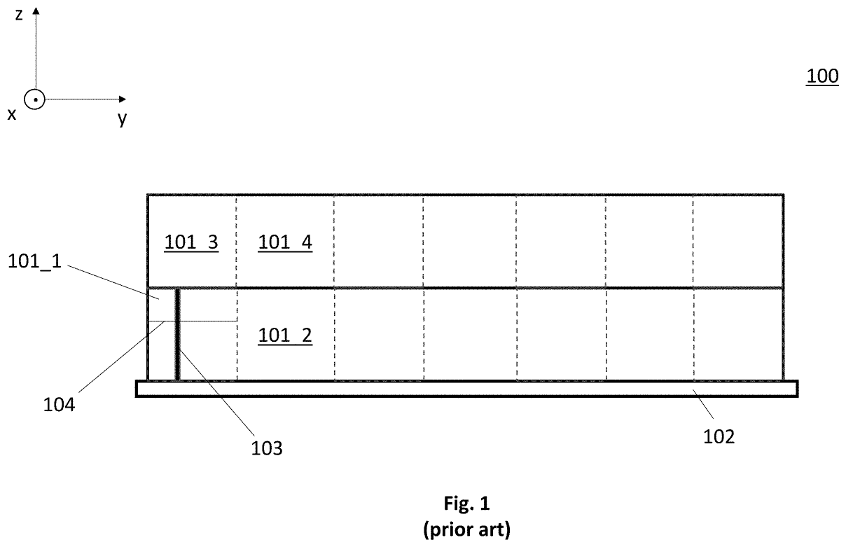

FIG. 1 depicts a side view of a manufactured flash memory chip 100. As observed in FIG. 1, the flash memory chip 100 is composed of multiple blocks 101 (for ease of drawing only four of the blocks are labeled). Each block includes an array densely packed pillars (or “columns”) that are formed amongst the metal wiring layers above a semiconductor chip substrate 102 (for each of drawing, only one pillar 103 is depicted and labeled in block 101_1). Each pillar includes, e.g., approximately 100 storage cells that are vertically stacked along the pillar's vertical (z) axis.

A word line is a horizontal wire that runs through a particular block along the y axis and couples to the same height cell along each of the pillars in the block that are positioned at the same x axis location as the word line (for ease of drawing, FIG. 1 only depicts one word line 104 within block 101_1). A page is the group of storage cells coupled to a group of one or more word lines within a same block (where, in the case of multiple word lines per page, the word lines of a same page are typically located at a same z height but different x axis locations within the block).

Generally, writes to and reads from the flash memory chip 100 are performed at page granularity. Here, an address that is provided to the memory chip essentially resolves to a particular block within the memory chip and the word line(s) within the block that correspond to the targeted page.

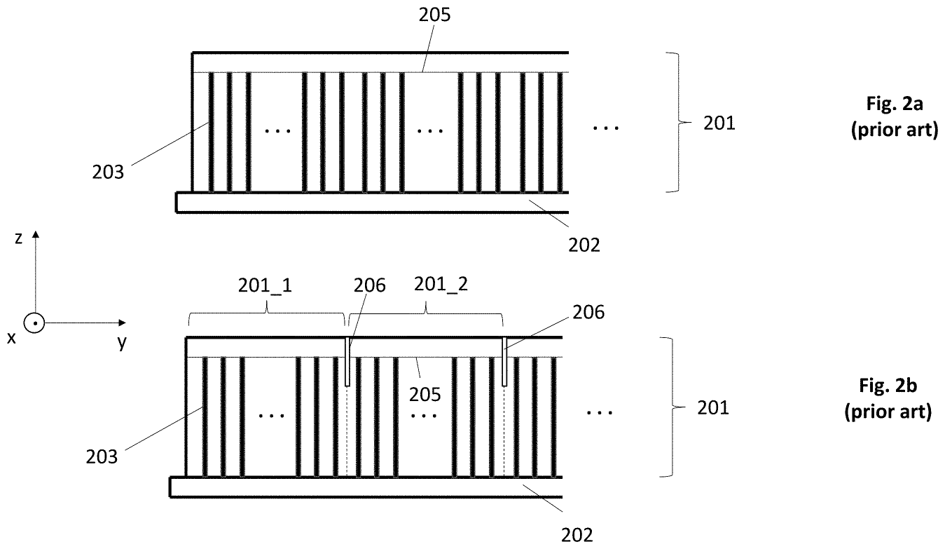

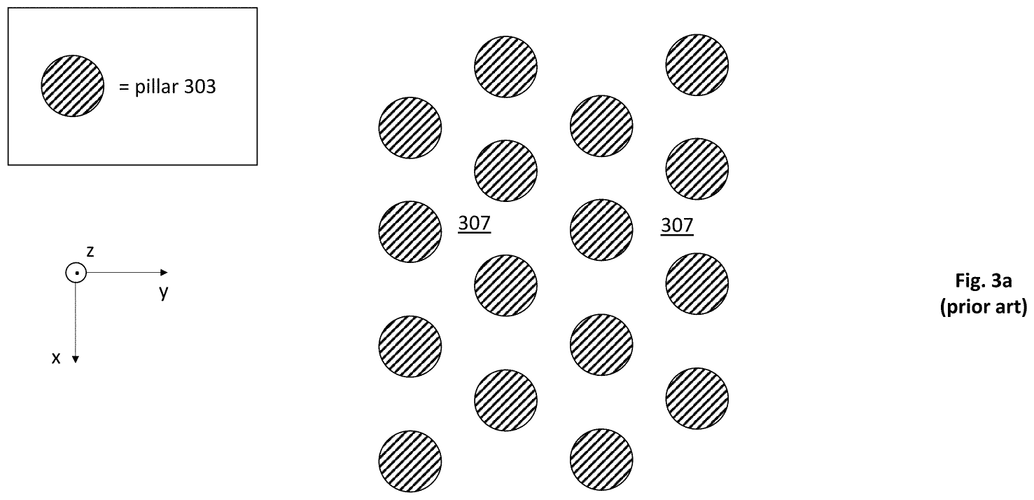

During manufacturing of the flash memory chip, referring to FIG. 2a, a large multilayer structure 201 is constructed that includes the pillars 203 and word lines (not shown) for multiple blocks. Individual blocks 201_1, 201_2 are then formed from the structure 201, referring to FIG. 2b, by vertically etching into the upper region of the structure 201 and filling the voids with dielectric 206. Here, the vertical etching “cuts” through an upper layer of polysilicon 205 that is used to form electrode structures for access transistors that are associated with the pillars and/or wiring that couples to such electrode structures. After the etch and dielectric fill, the pillars on either side of the dielectric 206 are electrically isolated from one another which, in turn, helps to form individual blocks 201_1, 201_2 that are electrically isolated from one another.

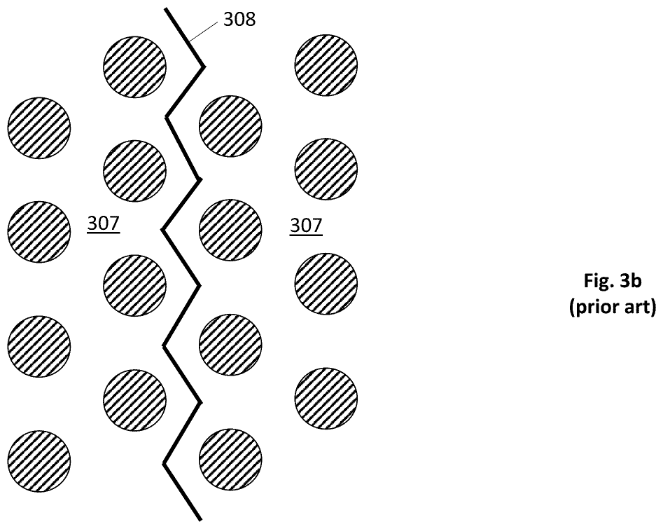

FIGS. 3a and 3b show a top-down view of the etch process. Here, FIG. 3a shows a top down view of a portion of the large multilayer structure before the etch. As observed in FIG. 3a, the portion of the large multilayer structure includes a number of densely packed pillars 303 separated by upper dielectric material(s) 307 (the upper polysilicon layer 205 that is to be etched is beneath the upper dielectric material(s) 307). The etch is then performed as observed in FIG. 3b. Here, the etch 308 follows a “weave” pattern so that the etched region 308 ideally remains a maximal distance away from the pillars on either side of the etch 308.

A problem is that with each next generation of manufacturing technology, the pillars 303 are placed closer to one another to effect larger storage densities. The reduced pillar spacing is making it difficult to implement the weave pattern etch 308. Essentially, the spacing between the pillars 303 has become comparable to the tolerance of the etch which performed with a traditional photoresist and patterning approach. As such, the etch can laterally extend to the pillars 303 and damage them.

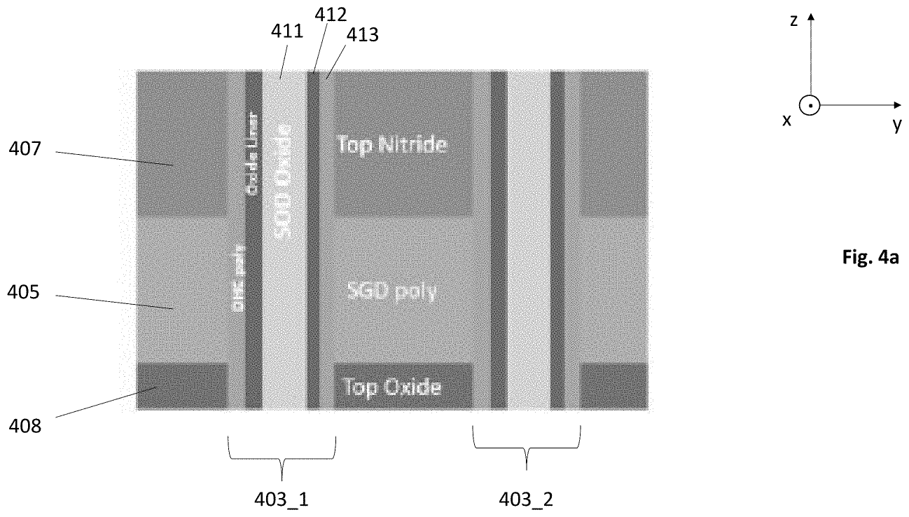

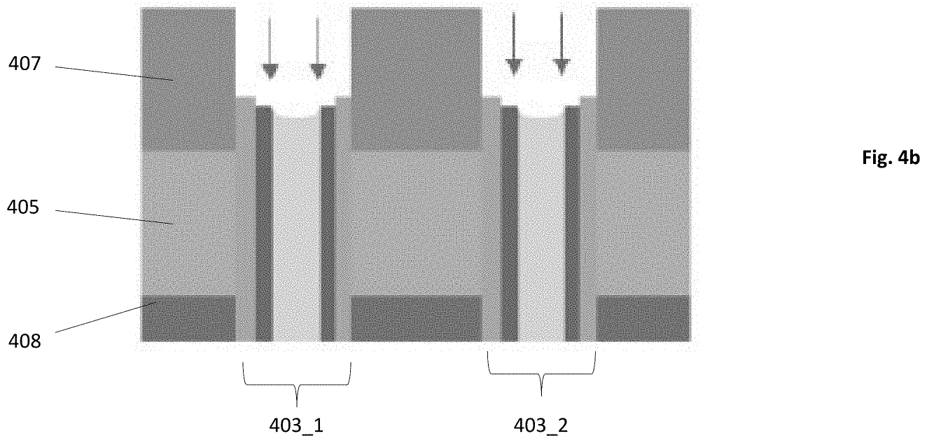

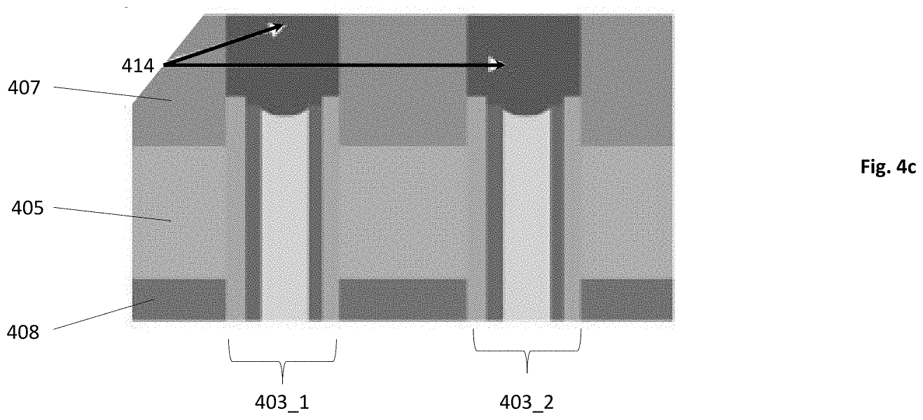

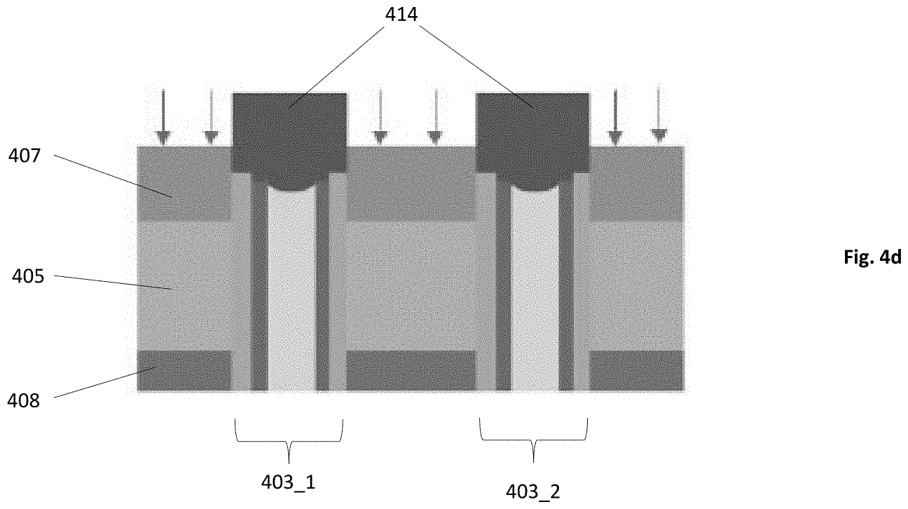

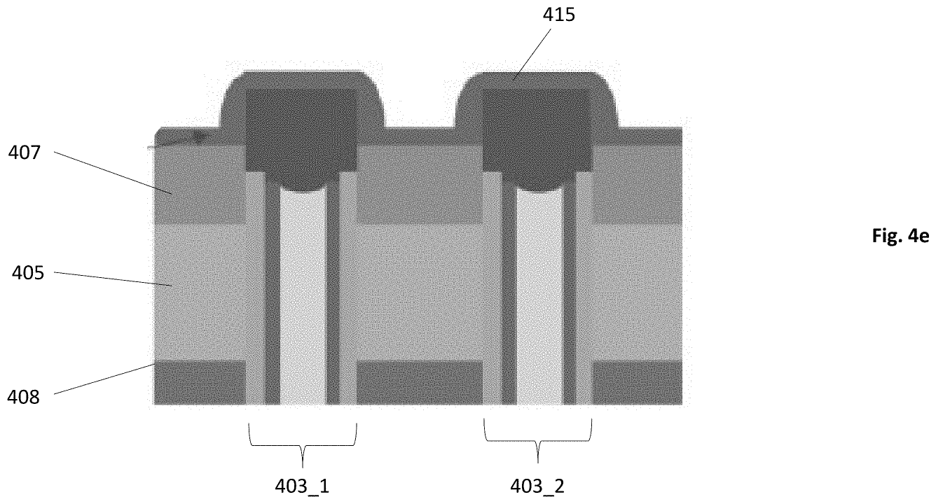

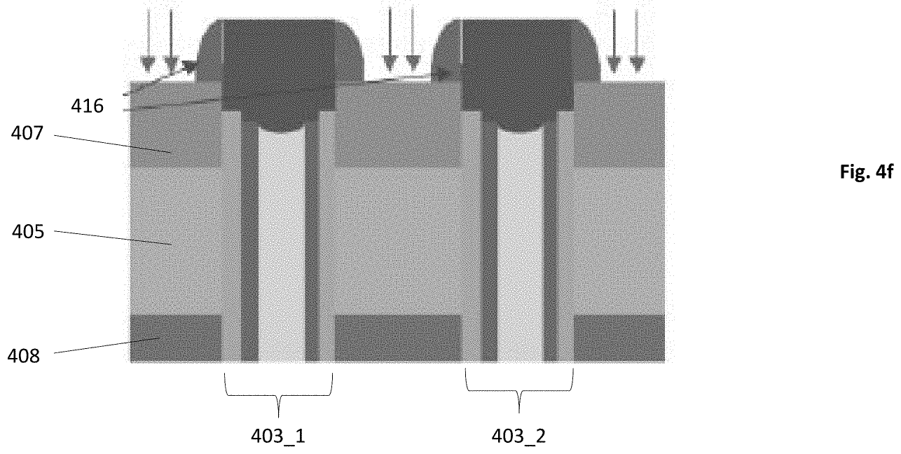

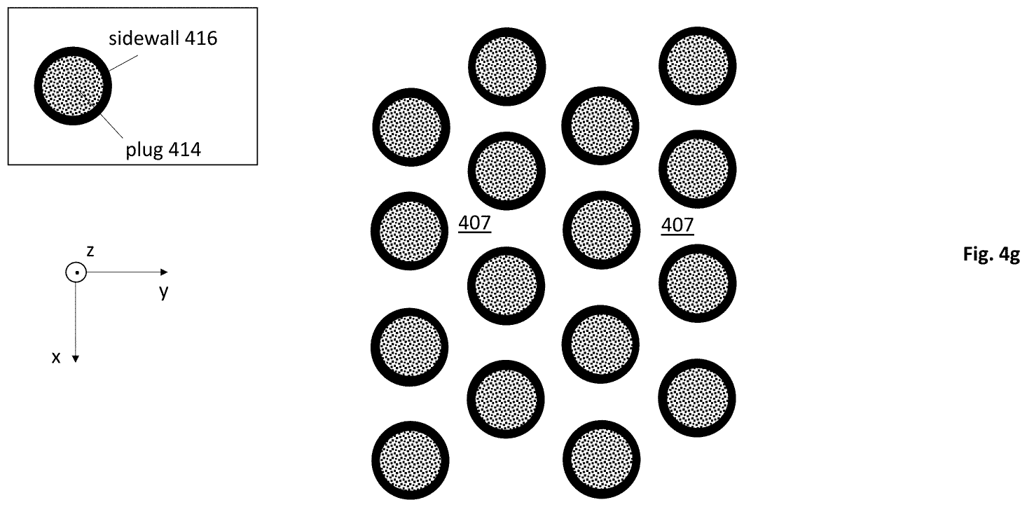

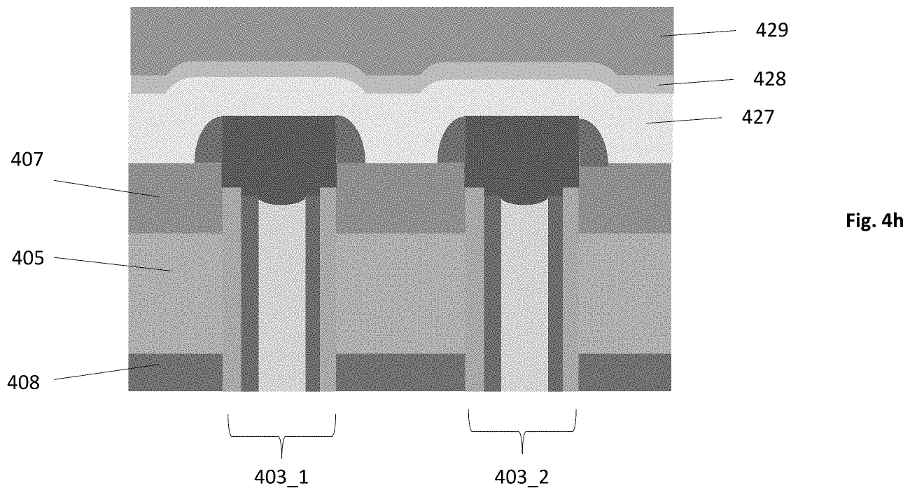

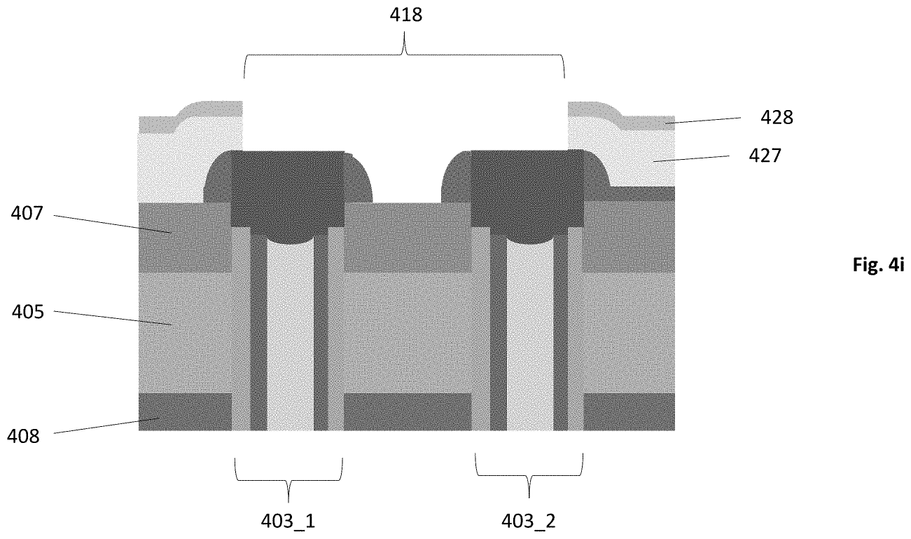

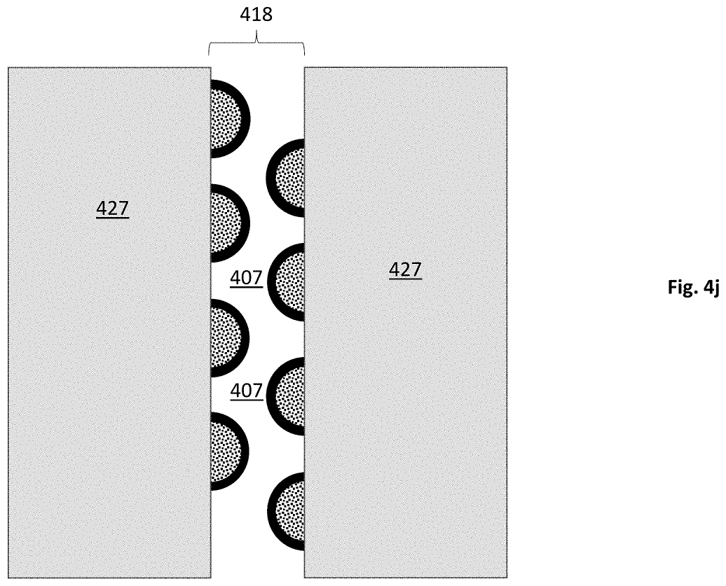

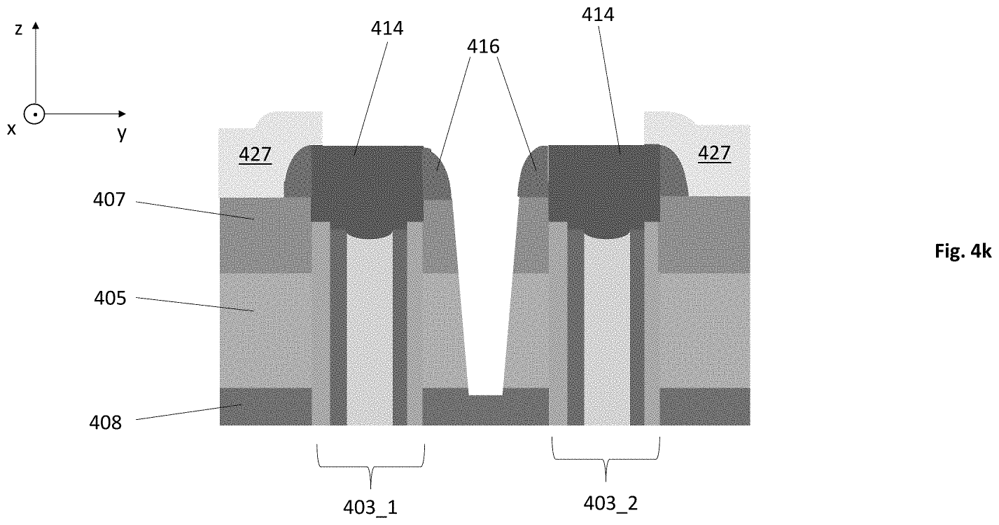

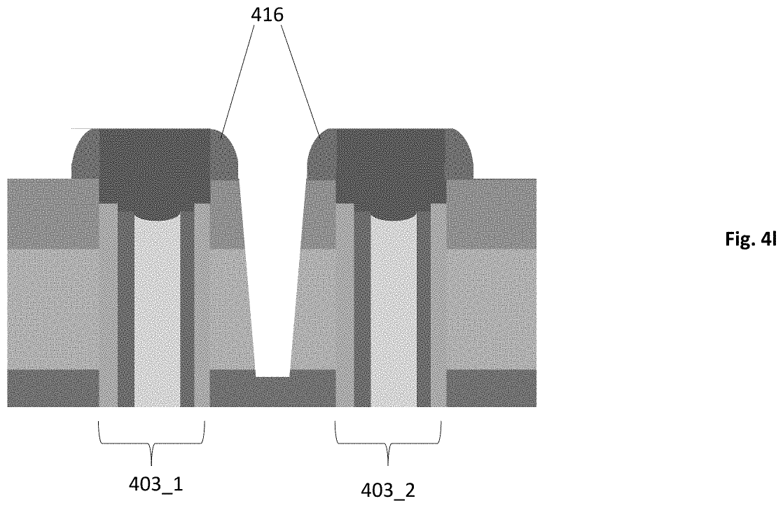

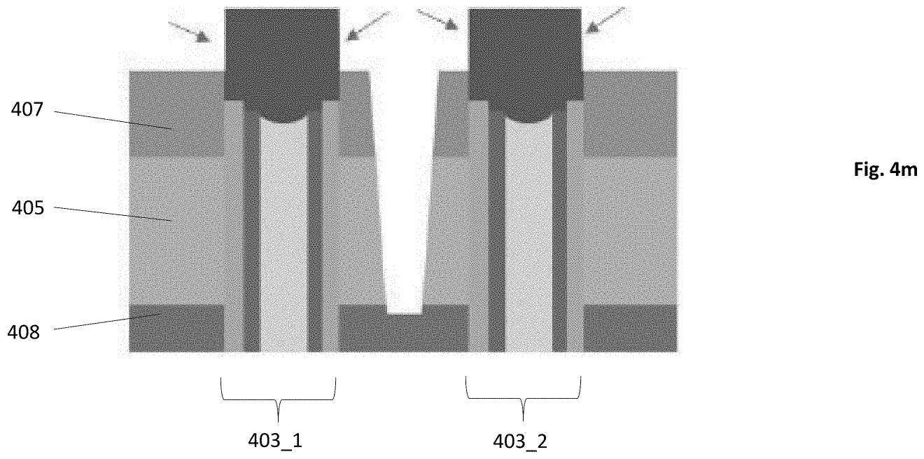

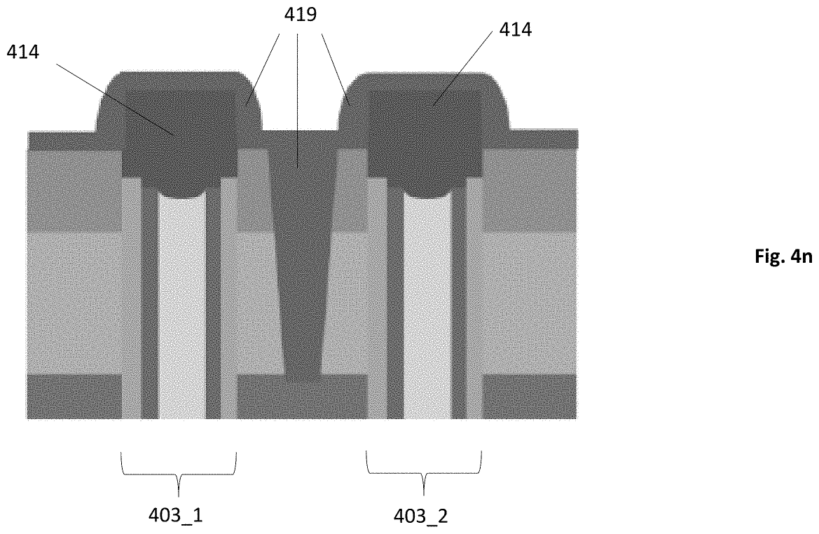

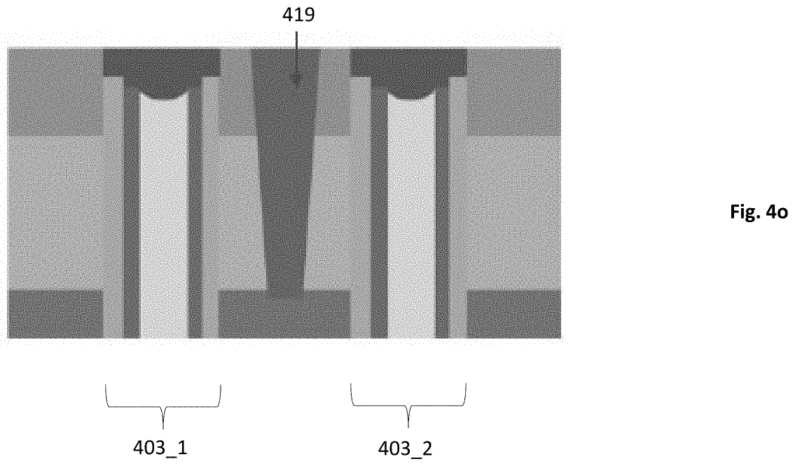

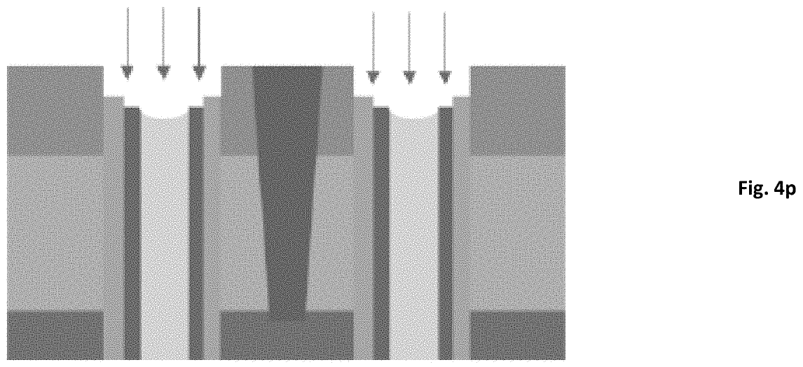

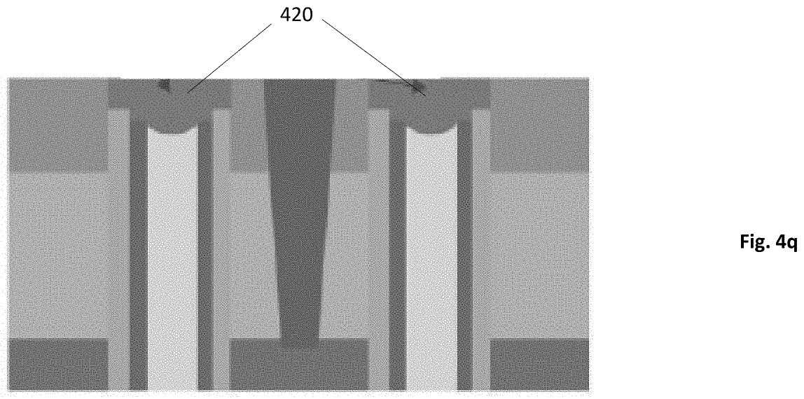

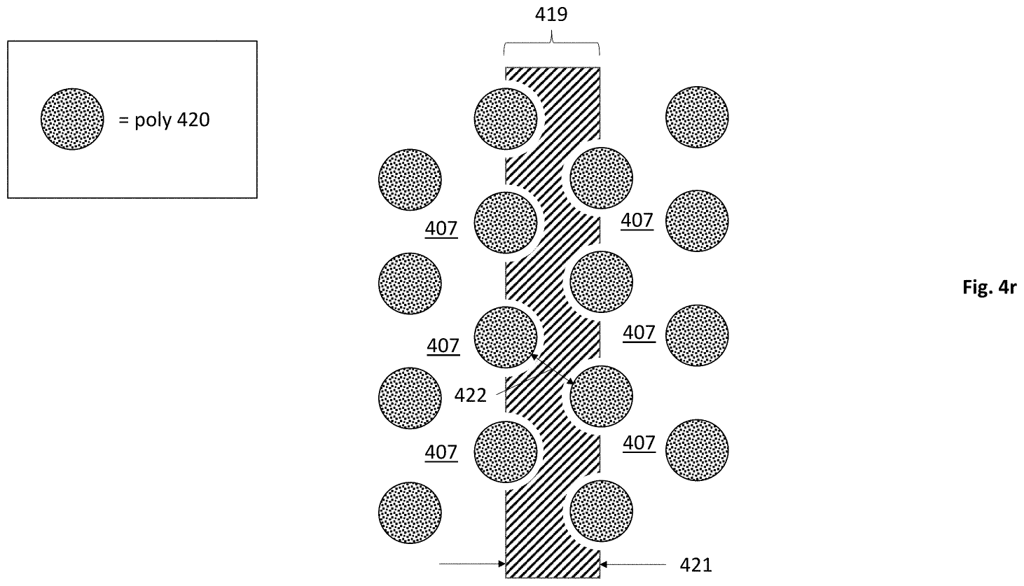

FIGS. 4a through 4r show an improved process for etching between the pillars. FIG. 4a shows a side view the upper region of a pair of pillars 403_1, 403_2 having a region between them where the etch and fill process is to take place. Each pillar includes an inner region of spin on dielectric (SOD) 411, a middle oxide liner 412 and an outer region polysilicon 413. Here, a pillar is substantially cylindrical, thus the SOD 411 acts an inner core whose outer circumference is surrounded by the oxide liner 412. The outer circumference of the oxide liner 412, in turn, is surrounded by the polysilicon 413.

The material through which the pillars extend includes a polysilicon layer 405 between a first dielectric (nitride) layer 407 and a second dielectric (oxide) layer 408. Here, polysilicon layer 405 corresponds to the polysilicon layer 205 that is to be etched through to isolate the pillars 403_1, 403_2 from one another and the nitride layer 407 corresponds to the upper dielectric material 307 that is etched through in order to etch the polysilicon layer 405. In various embodiments, the polysilicon layer 405 is used to form, toward the top end of each pillar, an access transistor (e.g., a source-gate-drain SGD transistor) that is used to access the pillar (such as an electrode of an access transistor) and/or the electrical wiring that couples to the transistor.

Referring to FIG. 4b, a selective etch is performed that etches into the pillar's core 411 and circumferential layers 412, 413 but not the nitride layer 407. Referring to FIG. 4c, a tungsten plug 414 is then formed (e.g., deposited) within the cavities that were formed by the etch in the nitride layer on the exposed, recessed pillars. After the plug deposition, the upper surface is polished, e.g., by chemical mechanical polish (CMP) to produce a substantially even upper surface.

In various embodiments, for reasons that will be made more clearly below, the plug material 414 is made of a material that can withstand (not be etched by) an etch (selective or otherwise) of the first dielectric 407 and polysilicon 405 layers that the pillars 403_1, 403_2 extend through. In the particular embodiment being described herein, the first dielectric is nitride 407. Tungsten (or a tungsten alloy) is a material that can withstand a nitride etch and polysilicon etch and therefore is chosen for the plug material 414. Other possible materials include titanium (Ti), titanium and nitride (e.g., TiN), aluminum and oxide (e.g., Al₂O₃), poly-silicon, tungsten and silicide (e.g., WSi) and magnesium and oxide (e.g., MgO), carbon among others.

Referring to FIG. 4d, a selective, dry etch is performed that etches the nitride layer 407 but not the tungsten plug 414. The nitride etch exposes an upper portion of the tungsten plug 414 that extends above the recessed nitride layer 407. Then, as observed in FIG. 4e, the exposed surface of the overall structure is conformally deposited with a third dielectric layer 415 such as an oxide.

As observed in FIG. 4f, the third dielectric layer 415 is then anisotropic etched such that the etching is primarily vertically downward (rather than lateral) as depicted. The etch removes the planar layer of the oxide 415 but not the conformal coating of the oxide 415 around the side circumference of the plugs 414 effectively leaving sidewalls 416 on the plugs 414.

FIG. 4g shows a top down view after the etch of the third dielectric layer 415. Here, the pillars are covered with tungsten plugs 414 having sidewalls 416 formed around their respective circumferences.

As observed in FIG. 4h, carbon hard mask, 427, dielectric anti-reflective coating (DARC) 428, and photoresist 429 layers are then sequentially applied to the exposed surface of FIG. 4g. The photoresist layer 429 is then patterned and etched to expose the DARC 428 above a region 418 that encompasses inner regions of the plugs 414 and the space between the plugs 414. The exposed DARC 428 within region 418 and the carbon hard mask 427 beneath the exposed DARC 428 within region 418 are then sequentially removed followed by the removal of the photoresist layer 429 leaving the structure of FIG. 4i.

The DARC 428 layer is then removed leaving the patterned hard mask 427 outside region 418. FIG. 4j shows a top down view of the resulting structure which includes the remaining portions of the hard mask 427, the exposed inner regions of the plugs and the exposed upper nitride 407 between the plugs.

As observed in FIG. 4k, a selective (e.g., dry) etch is then performed that primarily etches into the upper nitride 407 and polysilicon layers 405 without substantially etching into the dielectric sidewall material 416 and tungsten plug 414. In various embodiments the etch is a chemical etch that reacts with the first dielectric layer 407 and the polysilicon layer 405 but not the sidewall 416 and plug materials 414. The etch extends through the polysilicon layer 405 thereby electrically isolating the pillars 403_1, 403_2 from one another. The oxide layer 408 acts as an etch stop.

Importantly, owing to the carbon mask 427, sidewalls 416 and plugs 414 (which are not etched), the etch of FIG. 4k is essentially a self-aligned etch whose (e.g., minimum) dimension is determined by the spacing between the respective sidewalls 416 of plugs 414. Because the spacing of the pillars 403_1, 403_2 and the sidewall thickness can be tightly controlled, and because the rate and direction of the etch can be precisely controlled, the minimum dimension(s) of the void created by the etch can be tightly controlled.

As observed in FIGS. 4l and 4m, the hard mask 427 and then the sidewalls 416 are removed which leaves exposed the upper regions of the plugs 414, the upper nitride 407 and the etched region between the pillars 403_1, 403_2. With respect to the sidewall 416 etch of FIG. 4m, in an embodiment, the sidewall material 416 is doped so that the sidewall etch of FIG. 4m is selective to the sidewall material 416 but not the lower oxide layer 408. As such, the etch removes the sidewalls 416 but does not damage (or appreciably damage) the exposed surface of oxide layer 408.

Then, as observed in FIG. 4n, the exposed surface of the overall structure is covered in a dielectric 419 (e.g., with a high aspect ratio process (HARP) oxide) which fills the void between the pillars created by the etch of FIG. 4k. The resulting structure is then planarized, e.g., be CMP, so to remove the exposed plug material and the upper portion of the dielectric 419 as observed in FIG. 4o. Notably, the dielectric fill 419 between the pillars 403_1, 403_2 remains which preserves their electrical isolation.

As observed in FIGS. 4p and 4q, the remainder of the plug 414 is then removed (e.g., by a wet Tungsten etch) and their void is re-filled with polysilicon which form polysilicon plugs 420 that, e.g., can act as top electrodes for the pillars.

FIG. 4r shows a top down view of the completed structure. Notably, the dielectric between the pillars is a large region 419 filled with dielectric material rather than a weave. More specifically, the width 421 of the region 419 is greater than the distance 422 between neighboring plugs 420. Here, as described above, the spacings 422 between neighboring pillars can be 15 nm or lower but the width 421 of the dielectric filled region can be larger such as 20 nm or lower.

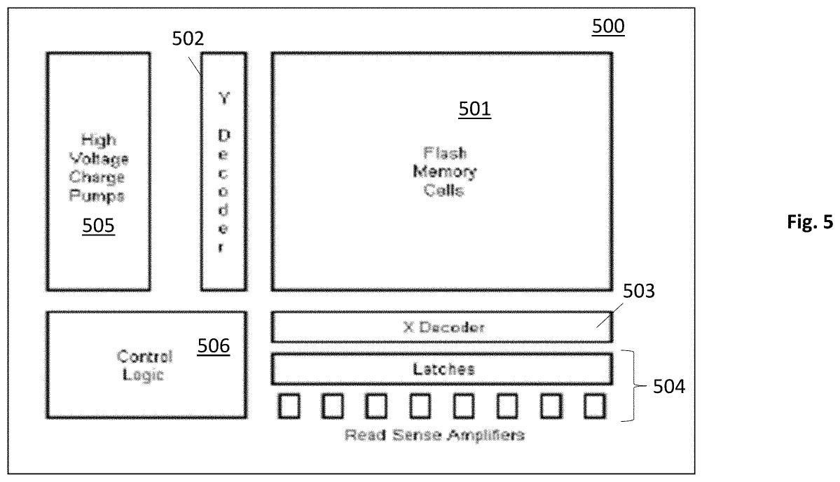

FIG. 5 shows an embodiment of a flash memory chip 500. As observed in FIG. 5, the flash memory chip 500 includes a memory cell array 501, an X decoder 502 and a Y decoder 503. The memory cell array 501 includes an array of storage cells, e.g., having a narrow self-aligned dielectric filled slit between pillars as described at length just above. The X and Y decoders 502, 503 resolve a page write (also referred to as page program) or page read to a particular page within the array 501. During a read operation, the read data is latched and sensed by latches and sense amplifiers 504. Charge pump circuitry 505 generates larger voltages than the memory chip's supply voltage for, e.g., program and/or erase operations. Control circuitry 505 controls the overall operation of the chip 500.

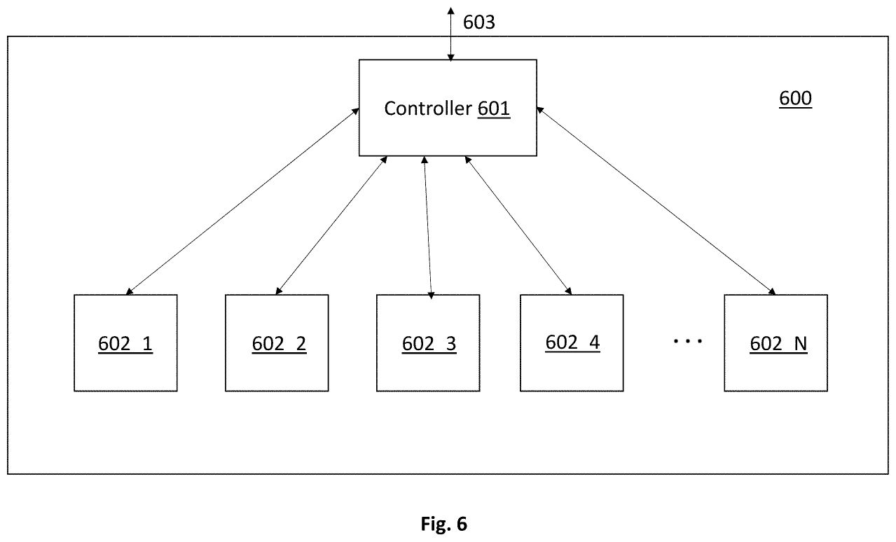

FIG. 6 shows an embodiment of a solid state drive (SSD) 600. The SSD 600 includes a controller 601 that receives commands (e.g., erase commands, program commands, read commands) from a host by way of a host interface (e.g., a PCIe interface, an NVMe interface, etc.). The controller is coupled to a plurality of flash memory chips 602, each of which can be implemented as the memory chip 500 described just above with respect to FIG. 5, and applies the received commands to the appropriate memory chips 602.

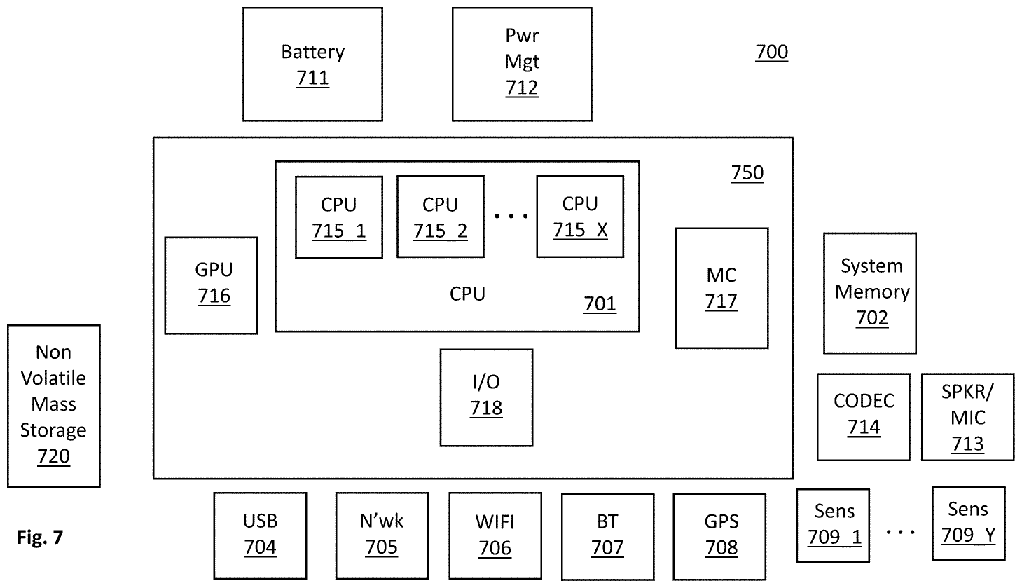

FIG. 7 depicts a basic computing system. The basic computing system 700 can include a central processing unit (CPU) 701 (which may include, e.g., a plurality of general purpose processing cores 715_1 through 715_X) and a main memory controller 717 disposed on a multi-core processor or applications processor, main memory 702 (also referred to as “system memory”), a display 703 (e.g., touchscreen, flat-panel), a local wired point-to-point link (e.g., universal serial bus (USB)) interface 704, a peripheral control hub (PCH) 718; various network I/O functions 705 (such as an Ethernet interface and/or cellular modem subsystem), a wireless local area network (e.g., WiFi) interface 706, a wireless point-to-point link (e.g., Bluetooth) interface 707 and a Global Positioning System interface 708, various sensors 709_1 through 709_Y, one or more cameras 710, a battery 711, a power management control unit 712, a speaker and microphone 713 and an audio coder/decoder 714.

An applications processor or multi-core processor 750 may include one or more general purpose processing cores 715 within its CPU 701, one or more graphical processing units 716, a main memory controller 717 and a peripheral control hub (PCH) 718 (also referred to as I/O controller and the like). The general purpose processing cores 715 typically execute the operating system and application software of the computing system. The graphics processing unit 716 typically executes graphics intensive functions to, e.g., generate graphics information that is presented on the display 703. The main memory controller 717 interfaces with the main memory 702 to write/read data to/from main memory 702. The main memory 702 can include one or more DIMMs having an RCD that controls data buffer to memory chip write training as discussed at length above. The power management control unit 712 generally controls the power consumption of the system 700. The peripheral control hub 718 manages communications between the computer's processors and memory and the I/O (peripheral) devices.

Other high performance functions such as computational accelerators, machine learning cores, inference engine cores, image processing cores, infrastructure processing unit (IPU) core, etc. can also be integrated into the computing system.

Each of the touchscreen display 703, the communication interfaces 704-707, the GPS interface 708, the sensors 709, the camera(s) 710, and the speaker/microphone codec 713, 714 all can be viewed as various forms of I/O (input and/or output) relative to the overall computing system including, where appropriate, an integrated peripheral device as well (e.g., the one or more cameras 710). Depending on implementation, various ones of these I/O components may be integrated on the applications processor/multi-core processor 750 or may be located off the die or outside the package of the applications processor/multi-core processor 750. The computing system also includes non-volatile mass storage 720 which may be the mass storage component of the system which may be composed of one or more non-volatile mass storage devices (e.g., hard disk drive, solid state drive, etc.). The non-volatile mass storage 720 may be implemented with any of solid state drives (SSDs), hard disk drive (HDDs), etc. Any/all of the SSDs can be implemented with the SSD 600 described above with respect to FIG. 6.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a flash memory chip comprising a self-aligned dielectric fill between pillars, the self-aligned dielectric fill extending through a polysilicon layer, the pillars having respective access transistors formed with the polysilicon layer, the self-aligned dielectric fill to electrically isolate the pillars.

2. The apparatus of claim 1 wherein the pillars are pillars of different blocks of the flash memory chip.

3. The apparatus of claim 1 wherein the self-aligned dielectric fill has a width greater than a spacing between neighboring pillars.

4. The apparatus of claim 1 wherein the pillars are not surrounded by the dielectric fill.

5. The apparatus of claim 1 wherein the respective electrodes of the access transistors are formed with the polysilicon layer.

6. The apparatus of claim 5 wherein the access transistors are source-gate-drain transistors.

7. The apparatus of claim 1 wherein the polysilicon layer is between a nitride layer and an oxide layer and the self-aligned dielectric fill extends through the nitride layer and the polysilicon layer and ends at the oxide layer.

8. A solid state drive comprising:
a host interface;
a controller coupled to the host interface;
a plurality of flash memory chips coupled to the controller, at least one of the flash memory chips comprising a self-aligned dielectric fill between pillars, the self-aligned dielectric fill extending through a polysilicon layer, the pillars having respective access transistors formed with the polysilicon layer, the self-aligned dielectric fill to electrically isolate the pillars.

9. The solid state drive of claim 8 wherein the pillars are pillars of different blocks of the flash memory chip.

10. The solid state drive of claim 8 wherein the self-aligned dielectric fill has a width greater than a spacing between neighboring pillars.

11. The solid state drive of claim 8 wherein the pillars are not surrounded by the dielectric

12. The solid state drive of claim 8 wherein respective electrodes of the access transistors are formed with the polysilicon layer.

13. The solid state drive of claim 12 wherein the access transistors are source-gate-drain transistors.

14. The solid state drive of claim 8 wherein the polysilicon layer is between a nitride layer and an oxide layer and the self-aligned dielectric fill extends through the nitride layer and the polysilicon layer and ends at the oxide layer.

15. A computer comprising:
a plurality of processing cores;
a main memory;
a memory controller coupled between the main memory and the plurality of processing cores;
an I/O control hub coupled to the memory controller;
an SSD coupled to the I/O control hub, the SSD comprising i), ii) and iii) below:
i) a host interface;
ii) a controller coupled to the host interface;
iii) a plurality of flash memory chips coupled to the controller, at least one of the flash memory chips comprising a self-aligned dielectric fill between pillars, the self-aligned dielectric fill extending through a polysilicon layer, the pillars having respective access transistors formed with the polysilicon layer, the self-aligned dielectric fill to electrically isolate the pillars.

16. The apparatus of claim 15 wherein the pillars are pillars of different blocks of the flash memory chip.

17. The apparatus of claim 15 wherein the self-aligned dielectric fill has a width greater than a spacing between neighboring pillars.

18. The apparatus of claim 15 wherein the pillars are not surrounded by the dielectric fill.

19. The apparatus of claim 15 wherein respective electrodes of the access transistors are formed with the polysilicon layer.

20. The apparatus of claim 15 wherein the polysilicon layer is between a nitride layer and an oxide layer and the self-aligned dielectric fill extends through the nitride layer and the polysilicon layer and ends at the oxide layer.
